(19) United States
(12) Patent Application Publication
(10) Pub. No.: US 2009/0102039 A1
(43) Pub. Date: Apr. 23, 2009

(54) Package on package structure

(75) Inventors: Shih-Ping Hsu, Sinfong Township (TW); Kan-Jung Chia, Sinfong Township (TW); Shang-Wei Chen, Sinfong Township (TW)

Correspondence Address: BACON & THOMAS, PLLC, 625 SLATERS LANE, FOURTH FLOOR, ALEXANDRIA, VA, 22314-1176, US

(73) Assignee: Phoenix Precision Technology Corporation, Hsinchu (TW)

(21) Appl. No.: 12/285,818

(22) Filed: Oct. 15, 2008

(30) Foreign Application Priority Data
Oct. 17, 2007 (TW) 096138828

(51) Int. Cl. H01L 23/48

(52) U.S. Cl. 257/686; 257/E23.01

(57) ABSTRACT

The present invention relates to a package on package (PoP) structure, which comprises: a first packaging substrate having a plurality of conductive elements on its surface; a second packaging substrate having a plurality of conductive elements on its surface; and a surface-ceramic aluminum plate sandwiched between the first packaging substrate and the second packaging substrate. The surface-ceramic aluminum plate includes plural plated through holes extending through the layer. In addition, the first packaging substrate electrically conducts with the second packaging substrate through these plated through holes. The disclosed structure eliminates the warpage problem of PoP structure, and enhances the strength of PoP structure.

### BACKGROUND OF THE INVENTION

1. Field of the Invention

The present invention relates to a package on package (PoP) structure and, more particularly, to a stacked-die package structure (package structure with stack of dies), which is favorable for eliminating the warpage problem of a PoP structure caused by asymmetric stress as the PoP structure is formed by stacking packaging substrates with different types.

2. Description of Related Art

Customer demands of the electronic products, in particular 3C (Computer, Communication and Consumer Electronics) devices, continue to evolve rapidly and the main trends are portability, convenience, multi-functions, and miniaturization. In the study of packaging technique, the main stress falls on reducing the volume and the thickness of the package product by combining integrated circuits with different functions through the use of different packaging methods in reference to the prerequisites for lightness, thinness, shortness and smallness. However, conventional package using a single chip cannot achieve multi-functions and other demands at the same time. In order to achieve multi-functions and miniaturization, numerous attempts have been made by the industry to develop a PoP structure designed to vertically stack packaging substrates, each of which has integrated circuits thereon, through conductive elements (such as solder balls) so that the electrical functions are improved and the market demands are met.

In the conventional techniques, the PoP structure is formed by directly stacking packaging substrates. FIG. 1 shows a cross-sectional schematic view of a traditional PoP structure, which mainly comprises a first packaging substrate 1 and a second packaging substrate 2. The first packaging substrate 1 has a first surface 10 and a second surface 11 opposite to the first packaging substrate 1. The second packaging substrate 2 has a third surface 20 and a fourth surface 21 opposite to the third surface 20, and the fourth surface 21 has a plurality of conductive elements 22 disposed thereon. Therefore, the first packaging substrate 1 is electrically connected to the second packaging substrate 2 through the conductive elements 22 by directly stacking these packaging substrates 1 and 2.

However, after the packaging substrates have been stacked, the differences in the sizes of the packaging substrates, the number of chips of the packaging substrates, and the types of the packaging substrates may lead to asymmetric stress among the packaging substrates which in turn causes the warpage problem of the PoP structure. More seriously, due to the warpage problem, the chips of the packaging substrates may be broken, thus causing failure on electrical functions. Thereby, the yield of the PoP structure is greatly decreased. Accordingly, the warpage problem remains not only an unsettled problem of PoP technique but also an urgent problem needed to be overcome in the industry.

Therefore, it is desirable to provide an improved package on package structure to mitigate and/or obviate the aforementioned problems.

### SUMMARY OF THE INVENTION

In views of the above problems, the object of the present invention is to provide a PoP structure for eliminating the warpage problem of the PoP structure as the PoP structure is formed by stacking packaging substrates with different types.

Another object of the present invention is to provide a PoP structure for increasing the yield of the PoP structure.

To achieve the objects, the PoP structure of the present invention comprises: a first packaging substrate having a first surface and a second surface opposite to the first surface, wherein the second surface has a plurality of conductive elements disposed thereon; a second packaging substrate having a third surface and a fourth surface opposite to the third surface, wherein a plurality of conductive elements is disposed on the third surface; and a surface-ceramic aluminum plate sandwiched between the first and the second packaging substrate, wherein the surface-ceramic aluminum plate has a plurality of plated through holes extending through the surface-ceramic aluminum layer, and the first packaging substrate is electrically connected to the second packaging substrate through the plated through holes.

Accordingly, as the PoP structure is formed by stacking packaging substrates with different types, the surface-ceramic aluminum plate sandwiched between the packaging substrates supports and strengthens the PoP structure so as to eliminate the warpage problem of a PoP structure caused by asymmetric stress. Thereby, the reliability of a PoP structure is enhanced.

According to the PoP structure of the present invention, the first and the second packaging substrate can be a wire-bonding packaging substrate, a flip-chip packaging substrate, or a packaging substrate having chips embedded therein.

According to the PoP structure of the present invention, the conductive elements disposed on the surfaces of first and the second packaging substrate can be metal balls.

According to the PoP structure of the present invention, the material of the metal balls can be selected from the group consisting of copper, tin, lead, silver, nickel, gold, platinum, and an alloy thereof.

According to the PoP structure of the present invention, the surface-ceramic aluminum plate can be obtained by forming plural through holes on an aluminum plate by drilling, and then surface oxidizing the aluminum layer. Thereby, an aluminum oxide layer used for insulating is formed on the surface of the aluminum plate and the through holes. Moreover, the surface-ceramic aluminum plate is capable to strengthen the PoP structure.

According to the PoP structure of the present invention, the plated through holes are filled with metal paste, or the plated through holes comprise an insulating material filled in the plated through holes, and a conductive material is disposed on inner walls of the plated through holes and extends to cover parts of the surfaces on two sides of the surface-ceramic aluminum layer. Hence, the conductive elements of the first and the second packaging substrate are electrically connected to each other through the plated through holes. Besides, the material of the insulating material is not particularly limited as long as the material is insulating.

Accordingly, as the PoP structure is formed by stacking packaging substrates with different types, the surface-ceramic aluminum plate sandwiched between the packaging substrates supports and strengthens the PoP structure so as to eliminate the warpage problem of a PoP structure caused by asymmetric stress. Thereby, the reliability of a PoP structure is enhanced. In addition, the conductive elements disposed on the first and the second packaging substrate can electrically connect to each other through the plated through holes of the surface-ceramic aluminum plate so as to transmit electric signals.

### BRIEF DESCRIPTION OF THE DRAWINGS

FIG. 1 is a schematic view of a traditional PoP structure;

FIG. 2 is a schematic view of a PoP structure according to a preferred embodiment of the present invention;

FIG. 3A is a schematic view of a wire-bonding packaging substrate using the PoP structure according to the preferred embodiment of the present invention;

FIG. 3B is a schematic view of a flip-chip packaging substrate using the PoP structure according to the preferred embodiment of the present invention;

FIG. 3C a schematic view of a packaging substrate, having chips embedded therein, using the PoP structure according to the preferred embodiment of the present invention; and

FIG. 4 is a schematic view of a PoP structure according to another preferred embodiment of the present invention.

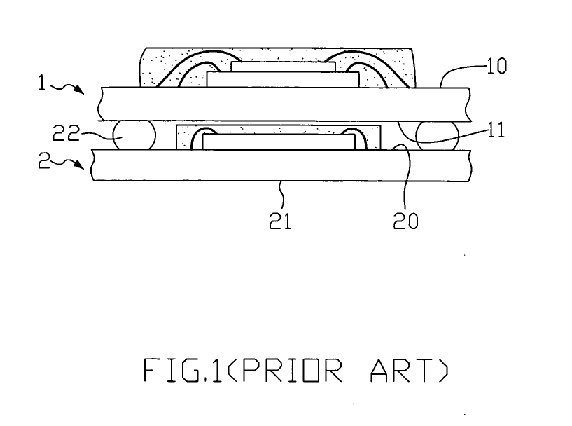

### DETAILED DESCRIPTION OF THE PREFERRED EMBODIMENT

Because of the specific embodiments illustrating the practice of the present invention, a person having ordinary skill in the art can easily understand other advantages and efficiency of the present invention through the content disclosed therein. The present invention can also be practiced or applied by other variant embodiments. Many other possible modifications and variations of any detail in the present specification based on different outlooks and applications can be made without departing from the spirit of the invention.

The drawings of the embodiments in the present invention are all simplified charts or views, and only exposed elements relative to the present invention. The elements revealed in the drawings are not necessarily aspects of the practice, and quantity and shape thereof are optionally designed. Further, the design aspect of the elements can be more complex.

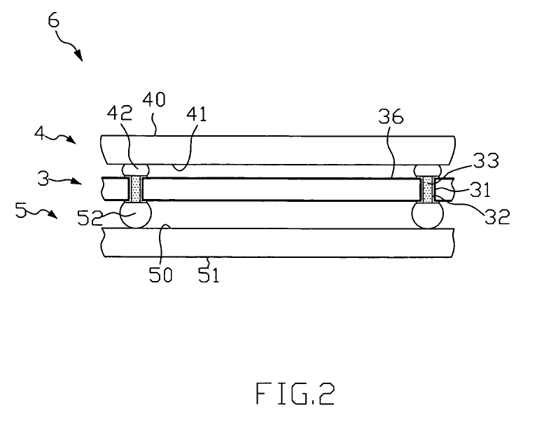

With reference to FIG. 2, there is shown a schematic view of a PoP structure according to a preferred embodiment of the present invention.

The PoP structure 6 comprises: a first packaging substrate 4, a second packaging substrate 5, and a surface-ceramic aluminum plate 3. The first packaging substrate 4 has a first surface 40 and a second surface 41 opposite to the first surface 40, and the second surface 41 has a plurality of conductive elements 42 disposed thereon. The second packaging substrate 5 has a third surface 50 and a fourth surface 51 opposite to the third surface 50, and the third surface 50 has a plurality of conductive elements 52 disposed thereon. The surface-ceramic aluminum plate 3 is sandwiched between the first packaging substrate 4 and the second packaging substrate 5. It is to be noted that the surface-ceramic aluminum plate 3 has an aluminum oxide layer 36 and a plurality of plated through holes 31 extending the surface-ceramic aluminum plate 3. The plated through holes 31 each comprise a conductive material 32 and an insulating material 33, wherein the conductive material 32 is disposed on inner wall of each plated through hole 31 and extends to cover parts of the surfaces on two sides of the surface-ceramic aluminum plate 3, and an insulating material 33 fills in the plated through holes 31. Therefore, the conductive elements 42 of the first packaging substrate 4 are electrically connected to the conductive elements 52 of the second packaging substrate 5 through the conductive material 32 of the plated through holes 31.

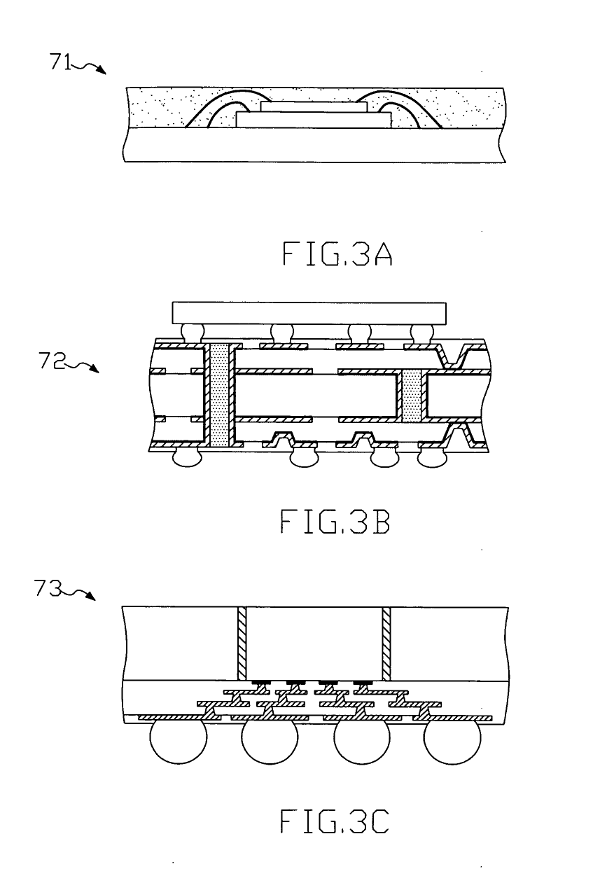

According to the variety of processes, any of the first packaging substrate 4 and the second packaging substrate 5 can be a wire-bonding packaging substrate 71 (as shown in FIG. 3A), a flip-chip packaging substrate 72 (as shown in FIG. 3B), or a packaging substrate having chips embedded therein 73 (as shown in FIG. 3C). In addition, the conductive elements 42 and 52 can be metal balls. These metal balls can be selected from the group consisting of copper, tin, lead, silver, nickel, gold, platinum, and an alloy thereof. Moreover, the sizes and the types of the first packaging substrate 4 and the second packaging substrate 5 can be the same or different.

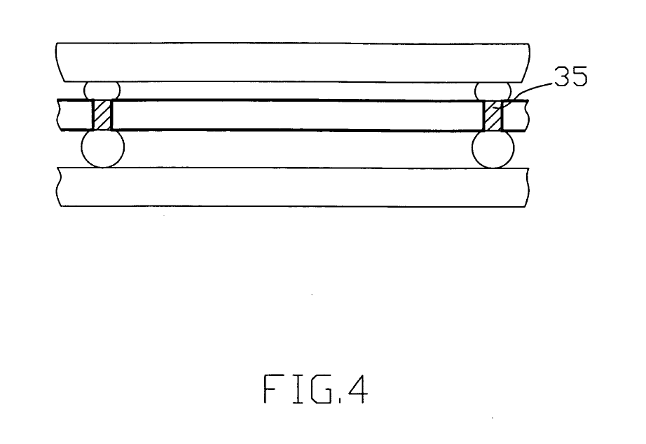

Actually, the packaging substrate 4 and the second packaging substrate 5 can be applied by varied embodiments. These packaging substrates described here are just instances. In one embodiment of the present invention, for example, the first packaging substrate 4 is a flip-chip packaging substrate (as shown in FIG. 3B) and the second packaging substrate 5 is a packaging substrate having chips embedded therein (as shown in FIG. 3C). Further, the plated through holes 31 can be applied by varied embodiments. For example, the plated through holes 31 are filled with metal paste 35 (as shown in FIG. 4).

It should be noted that the PoP structure 6 comprises the surface-ceramic aluminum plate 3 sandwiched between the packaging substrates 4 and 5 so that the surface-ceramic aluminum plate 3 can support and strengthen the PoP structure. In addition, the surface-ceramic aluminum plate 3 has a plurality of plated through holes 31 extending through the surface-ceramic aluminum plate 3 so that the conductive elements 42 and 52 of the first and the second packaging substrate 4 and 5 can electrically connect to each other. For these reasons, as the PoP structure is formed by stacking packaging substrates with different types, the warpage problem of the PoP structure caused by asymmetric stress can be eliminated. Thereby, the reliability of a PoP structure is enhanced.

Although the present invention has been explained in relation to its preferred embodiment, it is to be understood that many other possible modifications and variations can be made without departing from the scope of the invention as hereinafter claimed.

What is claimed is:

1. A package on package (PoP) structure, comprising:
a first packaging substrate having a first surface and a second surface opposite to the first surface, wherein the second surface has a plurality of conductive elements disposed thereon;
a second packaging substrate having a third surface and a fourth surface opposite to the third surface, wherein a plurality of conductive elements are disposed on the third surface; and
a surface-ceramic aluminum plate sandwiched between the first packaging substrate and the second packaging substrate, wherein the surface-ceramic aluminum plate has a plurality of plated through holes extending through the surface-ceramic aluminum layer, and the first packaging substrate is electrically connected to the second packaging substrate through the plated through holes.

2. The PoP structure as claimed in claim 1, wherein the first packaging substrate is a wire-bonding packaging substrate, a flip-chip packaging substrate, or a packaging substrate having chips embedded therein.

3. The PoP structure as claimed in claim 1, wherein the conductive elements are metal balls.

4. The PoP structure as claimed in claim 3, wherein the material of the metal balls is selected from the group consisting of copper, tin, lead, silver, nickel, gold, platinum, and an alloy thereof.

5. The PoP structure as claimed in claim 1, wherein the second packaging substrate is a wire-bonding packaging substrate, a flip-chip packaging substrate, or a packaging substrate having chips embedded therein.

6. The PoP structure as claimed in claim 1, wherein the plated through holes are each filled with metal paste, or the plated through holes each comprise an insulating material filled in the plated through holes, and a conductive material disposed on inner walls of the plated through holes and extends to cover parts of the surfaces on two sides of the surface-ceramic aluminum plate.

7. The PoP structure as claimed in claim 1, wherein the surface-ceramic aluminum plate is obtained by surface oxidizing an aluminum plate after drilling.
